(19) United States
(12) Patent Application Publication
(10) Pub. No.: US 2025/0316624 A1
(43) Pub. Date: Oct. 9, 2025

(54) SEMICONDUCTOR PACKAGES AND METHODS OF FABRICATING THEREOF

(71) Applicant: Taiwan Semiconductor Manufacturing Company, Ltd., Hsinchu (TW)

(72) Inventors: Han-Jong Chia, Walnut Creek, CA (US); Chieh-Yen Chen, Walnut Creek, CA (US); Ke-Han Shen, Walnut Creek, CA (US); Hung-Yi Kuo, Walnut Creek, CA (US)

(73) Assignee: Taiwan Semiconductor Manufacturing Company, Ltd., Hsinchu (TW)

(21) Appl. No.: 18/626,988

(22) Filed: Apr. 4, 2024

(51) Int. Cl. H01L 23/00; H01L 21/768; H01L 23/31; H01L 23/48; H01L 23/528; H01L 25/18

(52) U.S. Cl. CPC H01L 24/08; H01L 23/3185; H01L 23/481; H01L 24/80; H01L 25/18; H01L 21/76898; H01L 23/5286; H01L 2224/08145; H01L 2224/08225; H01L 2224/80895; H01L 2224/80896; H01L 2924/1431; H01L 2924/1436

(57) ABSTRACT

A semiconductor package includes an interposer, a first semiconductor chip disposed over the interposer and having a first surface and a second surface opposite to each other, and a second semiconductor chip disposed over the first semiconductor chip and having a top surface and a bottom surface opposite to each other. The semiconductor package further includes a dielectric sidewall disposed along a side of the first semiconductor chip and over the interposer, in which at least one first via structure is disposed vertically through the dielectric sidewall of the first semiconductor chip and electrically connected to a power distribution network (PDN).

### BACKGROUND

The semiconductor industry has experienced rapid growth due to continuous improvement in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-nanometer node), which allows more components to be integrated into a given area. As the demand for miniaturization, higher speed, and greater bandwidth, as well as lower power consumption and latency has grown recently, there has grown a need for smaller and more creative packaging techniques for semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically illustrates a cross-sectional view of an example semiconductor package in accordance with some embodiments.

FIG. 2 schematically illustrates an example semiconductor package in accordance with an embodiment.

FIG. 3 schematically illustrates another example semiconductor package in accordance with another embodiment.

FIG. 4 schematically illustrates a cross-sectional view of an example semiconductor package in more details in accordance with some embodiments.

FIG. 5 illustrates a cross-sectional view of an example hybrid bonding structure including a first interface structure and a second interface structure in accordance with some embodiments.

FIG. 6 is an example flowchart of a method for fabricating the semiconductor package in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. References to “or” may be construed as inclusive so that any terms described using “or” may indicate any of a single, more than one, and all of the described terms.

As semiconductor technologies further advance, stacked semiconductor devices, such as 3D integrated circuits (3D ICs or 3D-ICs), have emerged as an effective alternative to further reduce physical sizes of semiconductor devices. In a stacked semiconductor device, active circuits such as logic circuit, memory circuits, processor circuits, and the like are fabricated on different semiconductor wafers (or substrates), thereby forming respective semiconductor wafers (or dies). Two or more semiconductor wafers may be arranged on top of one another to further reduce the form factor of the stacked semiconductor device.

Two or more semiconductor wafers or dies (such as a bottom die, a top die, and a middle die) may be bonded together through suitable bonding techniques, for example, hybrid bonding, micro bumps, direct bonding, chemically activated bonding, plasma activated bonding, anodic bonding, eutectic bonding, glass frit bonding, adhesive bonding, thermo-compressive bonding, reactive bonding and/or the like. An electrical connection may be provided between the stacked semiconductor dies based on a plurality of through via structures, such as through substrate vias (TSV) (for example, through silicon vias) or the like.

The present disclosure is directed to a semiconductor package of a 3D IC. The semiconductor package includes an interposer, a first semiconductor chip disposed on the interposer and having a first surface and a second surface opposite to each other, a second semiconductor chip disposed on the first semiconductor chip and having a top surface and a bottom surface opposite to each other, and a dielectric sidewall disposed along a side of the first semiconductor chip and over the interposer. At least one first via structure, such as a through dielectric via (TDV), is disposed vertically through the dielectric sidewall of the first semiconductor chip and electrically connected to a power distribution network (PDN).

In some embodiments, the first semiconductor chip and the interposer are bonded to each other by a plurality of first hybrid bonds that are formed between facing surfaces thereof. In some embodiments, the first semiconductor chip and the second semiconductor chip are bonded to each other by a plurality of second hybrid bonds that are formed between facing surfaces thereof. In some embodiments, the second semiconductor chip is a memory stack, which includes a plurality of memory layers stacked on top of one another and then stacked on a logic base layer. In some embodiments, a first layer and a second layer of the plurality of memory layers of the memory stack are bonded to each other by a plurality of third hybrid bonds that are formed between facing surfaces thereof. In some embodiments, the first semiconductor chip is a graphics processing unit (GPU) chip. In some embodiments, the memory stack is a high bandwidth memory (HBM) stack.

With such schemes and structures, such as the TDVs vertically passing through the dielectric sidewall of the first semiconductor chip and electrically connected to a power distribution network (PDN), and direct hybrid bonding structures, demanded interfacing layers are reduced, interface thermal resistances are diminished, and an independent power distribution network (PDN) is provided, thereby advantageously improving system integration and power integration of the semiconductor package of the 3D IC.

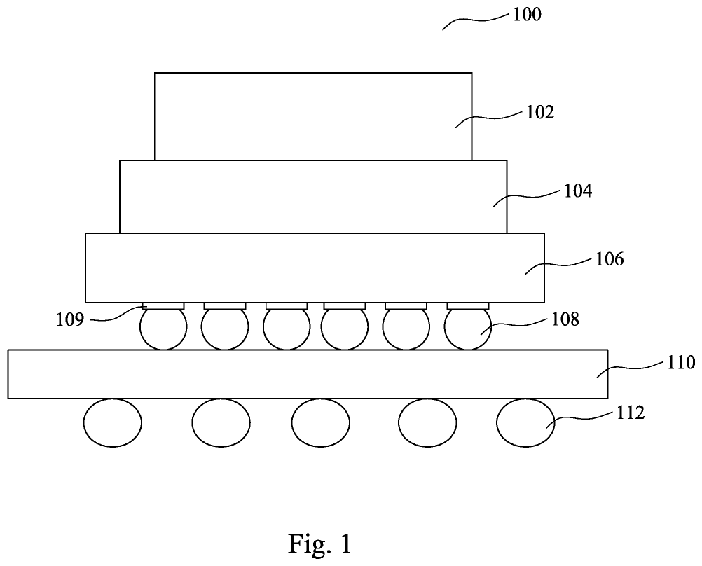

FIG. 1 illustrates a cross-sectional view of a semiconductor package (or device) 100 in accordance with various embodiments of the present disclosure. In one aspect, the semiconductor package 100 may sometimes be referred to as a three-dimensional integrated circuit (sometimes referred to as “3D IC”) with two or more levels of multiple semiconductor devices (sometimes referred to as “chips” or “dies”) stacked on top of one another. It should be understood that the semiconductor package 100 is simplified for illustrative purposes, and thus the arrangement of components or devices of the semiconductor package 100 can be configured in various other manners and/or the semiconductor package 100 can include any of other components or devices while remaining within the scope of the present disclosure.

In some embodiments of the present disclosure, the semiconductor package 100 includes a first die (or chip) 102 and a second die (or chip) 104 that are stacked on top of one another. The first die 102 and the second die 104 may be bonded to each other through suitable bonding techniques such as, for example, hybrid bonding, micro bumps, direct bonding, chemically activated bonding, plasma activated bonding, anodic bonding, eutectic bonding, glass frit bonding, adhesive bonding, thermo-compressive bonding, reactive bonding, or the like, and the combination thereof.

In one embodiment of the present disclosure, the top die 102 may include multiple active circuits, devices, components, or loads, such as a system-on-chip (SoC) device, a high-bandwidth memory device (HBM) device, or the like, while the bottom die 104 may include one or more passive circuits, devices, and/or loads, such as an integrated passive device, an integrated voltage regulator, or the like. In another embodiment of the present disclosure, the top die 102 may include both active and passive circuits, devices, and/or loads, and the bottom die 104 may also include both active and passive circuits, devices, and/or loads. In yet another embodiment of the present disclosure, the top die 102 may include passive circuits, devices, and/or loads, while the bottom die 104 may also include active circuits, devices, and/or loads.

In some embodiments of the present disclosure, the semiconductor package 100 further includes a redistribution structure 106 that is connected to the bottom chip 104. It should be appreciated that the illustration of the redistribution structure 106 in FIG. 1 is just schematic. The redistribution structure 106 may include a number of redistribution lines (RDLs), such as metal traces (or metal lines), and vias lying over or underlying the metal traces and connected to the metal traces, all of which are sometimes referred to as RDL routes. Such RDL routes may later be shown in one or more of the following figures. In some embodiments, the redistribution structure 106 can be a semiconductor interposer, which can be a thin semiconductor substrate that sits between two or more chips or dies, allowing them to communicate and work together, thereby providing routing for signals, power distribution, and even thermal management, for example.

In some embodiments of the present disclosure, the RDLs of the redistribution structure 106 are formed through plating processes, in which each of the RDLs includes a seed layer (not shown) and a plated metallic material over the seed layer. The seed layer may be formed using, for example, PVD or the like. A photo resist is then formed and patterned on the seed layer. The photo resist may be formed by spin coating or the like and may be exposed to light for patterning. The pattern of the photo resist corresponds to the RDLs. The patterning forms openings through the photo resist to expose the seed layer. A conductive material is formed in the openings of the photo resist and on the exposed portions of the seed layer. The conductive material may be formed by plating, such as electroplating or electroless plating, or the like. The seed layer and the plated metallic material may be formed of the same material or different materials. The conductive material may be a metal, like copper, titanium, tungsten, aluminum, or the like. Then, the photo resist and portions of the seed layer on which the conductive material is not formed are removed. The photo resist may be removed by an acceptable ashing or stripping process, such as using an oxygen plasma or the like. Once the photo resist is removed, exposed portions of the seed layer are removed, such as by using an acceptable etching process, such as by wet and/or dry etching. Thus, the remaining portions of the seed layer and conductive material form the RDLs of the redistribution structure 106.

In some embodiments of the present disclosure, the semiconductor package 100 further includes a number of micro bumps 108 (e.g., electrically) connecting the redistribution structure 106 to a package substrate 110. The micro bumps 108 may be metal pillars, controlled collapse chip connection (C4) bumps, micro bumps, electroless nickel-electroless palladium-immersion gold technique (ENEPIG) formed bumps, ball grid array (BGA) bumps, or the like. In an embodiment, the micro bumps 108 are C4 bumps. The micro bumps 108 may be formed by a sputtering, printing, electro plating, electroless plating, CVD, or the like. The micro bumps 108 may be solder free and have substantially vertical sidewalls. In some embodiments, a number of metal caps 109 are formed respectively on the tops of the micro bumps 108. In some embodiments, the metal caps 109 may include nickel, tin, tin-lead, gold, silver, palladium, indium, nickel-palladium-gold, nickel-gold, the like, or a combination thereof, and may be formed by a plating process.

In some embodiments of the present disclosure, the package substrate 110 may be, e.g., a printed circuit board (PCB) or the like, and may be electrically connected to the intermediate package (e.g., the top die 102 and the bottom die 104 bonded together with the redistribution structure 106) using the micro bumps 108. The package substrate 110 may be made of a semiconductor material, such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used as the semiconductor material of the package substrate 110. Additionally, the package substrate 110 may be a Silicon on Insulator (SOI) substrate. Generally, an SOI substrate includes a layer of a semiconductor material such as epitaxial silicon, germanium, silicon germanium, SOI, SGOI, or combinations thereof. The package substrate 110 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for package substrate 110.

In some embodiments of the present disclosure, the package substrate 110 may include metallization layers and vias, and bond pads over the metallization layers and vias (not shown). The metallization layers are designed to connect the various devices to form functional circuitry, which are sometimes referred to as package routes. The metallization layers may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). Such package routes may later be shown in one or more of the following figures.

In some embodiments of the present disclosure, the semiconductor package 100 further includes a number of conductive connectors 112 disposed on a back side of the package substrate 110 opposite to its front side facing the redistribution structure 106 as shown in FIG. 1. In some embodiments, the conductive connectors 112 may be formed from a conductive material such as solder, copper, aluminum, gold, nickel, silver, palladium, tin, the like, or a combination thereof. In some embodiments, the conductive connectors 112 are formed by initially forming a layer of solder through methods such as evaporation, electroplating, printing, solder transfer, ball placement, or the like. Once a layer of solder has been formed on the structure, a reflow may be performed in order to shape the conductive connectors 112 into desired bump shapes. Such conductive connectors 112 can operatively serve as package pins of the semiconductor package 100 that are configured to receive one or more supply voltages, in some embodiments. In some embodiments, some connectors 112 are electrically connected to a power distribution network (PDN) (not shown).

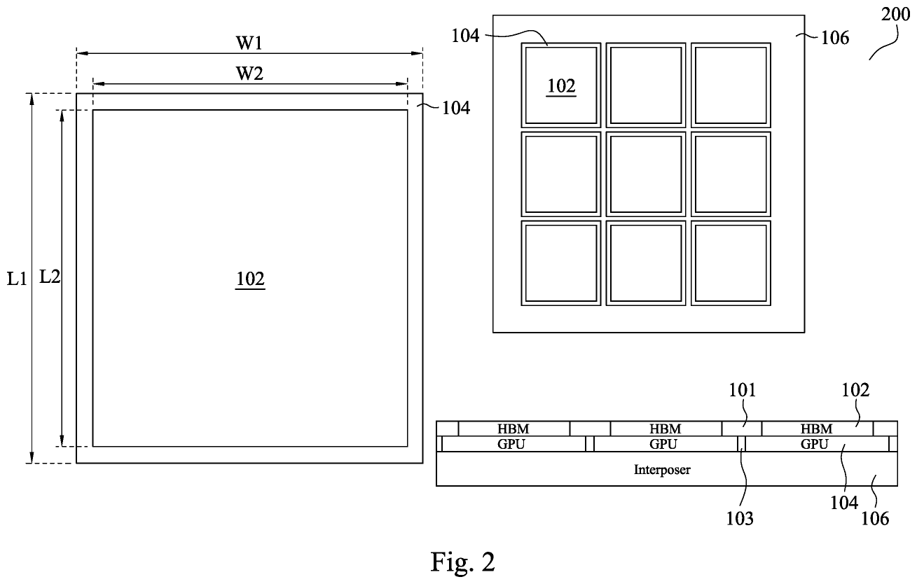

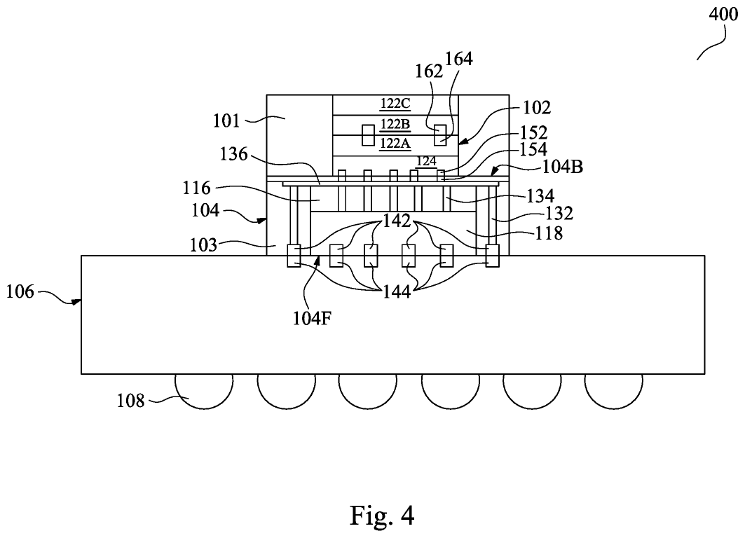

Further details regarding the components or devices and the bonding structures of the semiconductor package 100 will be depicted with respect to FIGS. 2-7 of the present disclosure. FIG. 2 schematically illustrates a layout and an arrangement of an example semiconductor package 200 in accordance with an embodiment of the present disclosure. In some embodiments, as shown in a top view and a cross-sectional view in FIG. 2, the semiconductor package 200 includes an interposer 106, a plurality (e.g., 3×3) of first semiconductor chips (such as GPUs) 104 disposed on the interposer 106, and a plurality (e.g., 3×3) of second semiconductor chips 102 (such as 3×3 memory stacks 102) respectively disposed on the plurality (e.g., 3×3) of first semiconductor chips 104. In some embodiments, the memory stacks 102 are high bandwidth memories (HBMs). In some embodiments, each of the memory stacks 102 includes a plurality of memory layers 122 (such as 122A, 122B, 122C . . . ) stacked on top of one another (as shown in FIG. 4). In some embodiments, the plurality of memory layers 122 of each of the memory stacks 102 includes a plurality of high bandwidth memory (HBM) layers and/or DRAM stacks. In some embodiments, the memory stacks 102 may include dynamic random access memory (DRAM) stacks. In some embodiments, the plurality of first semiconductor chips 104 are laterally separated from each other by a plurality of first dielectric sidewalls 103 thereof. In some embodiments, the plurality of second semiconductor chips 102 are laterally separated from each other by a plurality of second dielectric sidewalls 101 thereof. In some embodiments, an area of each of the plurality of first semiconductor chips 104 is in a range from about 14.5 mm (L1)×14.5 (W1) mm to about 20.5 mm (L1)×20.5 mm (W1), and an area of each of the plurality of second semiconductor chips 102 is in a range from about 13 mm (L2)×13 mm (W2) to about 19 mm (L2)×19 mm (W2). In some embodiments, a ratio of the area of each of the first semiconductor chips 104 to the area of each of the second semiconductor chips 102 is in a range from about 0.6 to about 2.5.

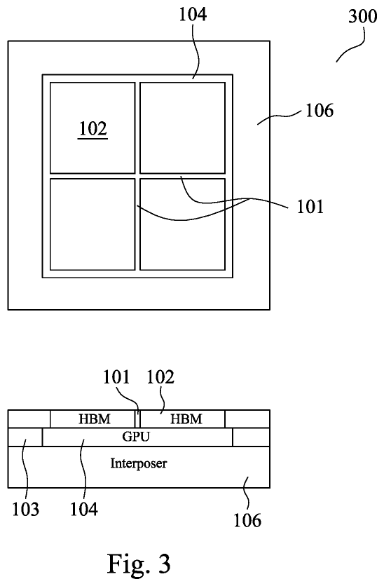

FIG. 3 schematically illustrates another example semiconductor package 300 in accordance with another embodiment of the present disclosure. In some embodiments, as shown in a top view and a cross-sectional view in FIG. 3, the semiconductor package 300 includes an interposer 106, a first semiconductor chip 104 disposed on the interposer 106, and a plurality (e.g., 2×2) of second semiconductor chips 102 that are disposed over the first semiconductor chip 104. As shown in FIG. 3, different from as shown in FIG. 2, in some embodiments, multiple smaller second semiconductor chips 102 can land onto a top surface of a single first semiconductor chip 104. In some embodiments, the first semiconductor chip 104 is a GPU, and the second semiconductor chips 102 are memory stacks. In some embodiments, each of the memory stacks 102 includes a plurality of memory layers 122 (such as 122A, 122B, 122C . . . ) stacked on top of one another (as shown in FIG. 4). In some embodiments, the plurality of memory layers 122 of each of the memory stacks 102 includes a plurality of high bandwidth memory (HBM) layers and/or DRAM stacks. In some embodiments, the first semiconductor chip 104 includes a plurality of first dielectric sidewalls 103 that laterally separate this first semiconductor chip 104 from adjacent other first semiconductor chips 104. In some embodiments, the plurality of second semiconductor chips 102 include a plurality of second dielectric sidewalls 101 that laterally separate adjacent second semiconductor chips 102 from each other.

FIG. 4 schematically illustrates a cross-sectional view of an example semiconductor package 400 corresponding to the semiconductor package 100 in FIG. 1 in more details in accordance with some embodiments of the present disclosure. It should be noted that the cross-sectional view of FIG. 4 is merely illustrated as an example, and should not limit a scope of the present disclosure. For instance, relative arrangements of the devices illustrated in the cross-sectional view can be rearranged, while remaining within the scope of the present disclosure.

In some embodiments of the present disclosure, the semiconductor package 400 includes an interposer 106, a first semiconductor chip 104 disposed on the interposer 104 and having a first surface (e.g., on a frontside) 104F and a second surface (e.g., on a backside) 104B opposite to each other, a second semiconductor chip (such as a memory stack) 102 disposed on the first semiconductor chip 104 and having a top surface and a bottom surface opposite to each other, and dielectric sidewalls 103 disposed along sides of the first semiconductor chip 104 and over the interposer 106.

In some embodiments, one or more first via structures (such as through dielectric vias TDVs) 132 are disposed vertically through the dielectric sidewalls 103 of the first semiconductor chip 104. In some embodiments, the TDVs 132 are electrically connected to a power distribution network (PDN) (not shown) through the interposer 106, thereby vertically transferring power through the first semiconductor chip 104 to other devices (such as the second semiconductor chip 102) of the semiconductor package 400. In some embodiments, the first semiconductor chip 104 is a GPU chip. In some embodiments, the second semiconductor chip 102 is a memory stack. In some embodiments, the memory stack 102 is a high bandwidth memory (HBM) stack. In some embodiments, the HBM stack 102 includes a logic base layer 124, and a plurality of HBM layers 122 (such as 122A, 122B, 122C, . . . ) that are disposed over the logic base layer 124 and stacked on top of one another.

In some embodiments, the first semiconductor chip 104 is flipped so that a frontside 104F thereof faces a top surface of the interposer 106 and a backside 104B thereof faces a bottom surface of the second semiconductor chip 102. In some embodiments, the first semiconductor chip 104 includes a silicon portion 116, a redistribution layer (RDL) portion 118, and second via structures (such as through silicon vias, so-called “TSVs”) 134 that pass through the silicon portion 116. In some embodiments, the TDVs 132 extend a greater vertical distance than the TSVs 134 extend. In some embodiments, the first semiconductor chip 104 includes a metal line 136 on the backside 104B thereof. In some embodiments, the metal line 136 is electrically connected to the TDVs 132 and TSVs 134. In some embodiments, the metal line 136 is made of a metal material such as copper, titanium, tungsten, aluminum, or the like.

In some embodiments of the present disclosure, the first semiconductor chip 104 and the interposer 106 are bonded to each other by a plurality of first hybrid bonds that are formed between the front surface 104F of the first semiconductor chip 104 and a top surface of the interposer 106. In some embodiments of the present disclosure, the plurality of first hybrid bonds are formed by a plurality of first bonding pad metals (BPMs) 142 that are embedded into and flush with the front surface 104F of the first semiconductor chip 104 and a plurality of second bonding pad metals (BPMs) 144 that are embedded into and flush with the top surface of the interposer 106. The plurality of first bonding pad metals (BPMs) 142 and the plurality of second bonding pad metals (BPMs) 144 are respectively aligned to and in contact with each other, and thus attached each other, thereby no space or gap existing between the front surface 104F of the first semiconductor chip 104 and the top surface of the interposer 106. As such, thermal resistance between the front surface 104F of the first semiconductor chip 104 and the top surface of the interposer 106 is greatly reduced.

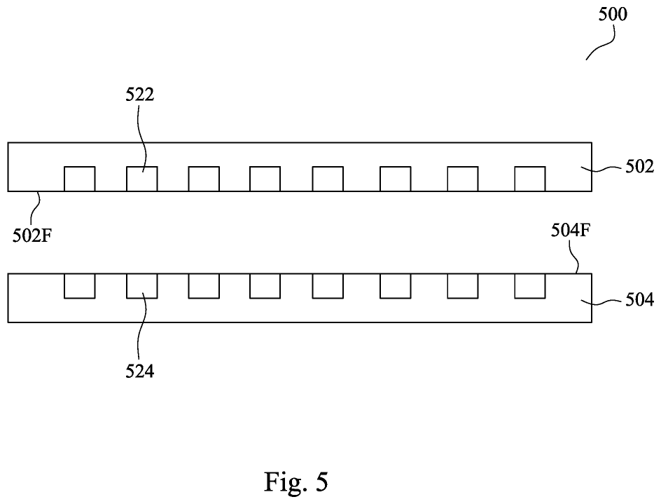

FIG. 5 illustrates a cross-sectional view of an example hybrid bonding structure 500 that includes a fist interface structure 502 and a second interface structure 504 in accordance with some embodiments of the present disclosure. In some embodiments, the first interface structure 502 and the second interface structure 504 are made of a dielectric material, and a planar bottom surface (e.g., front surface) 502F of the first interface structure 502 is disposed facing a planar top surface (e.g., front surface) 504F of the second interface structure 504. In some embodiments, a plurality of first bonding pad metals (BPMs) 522 are embedded into and flush with the planar bottom surface 502F of the first interface structure 502, and a plurality of second bonding pad metals (BPMs) 524 are embedded into and flush with the planar top surface 504F of the second interface structure 504. When the plurality of first BPMs 522 and the plurality of second BPMs 524 are aligned to and attached to each other, a direct hybrid bond (face to face) is formed between the first interface structure 502 and the second interface structure 504 through the plurality of first BPMs 522 of the planar front surface 502F of the first interface structure 502 and the plurality of second BPMs 524 of the planar front surface 504F of the second interface structure 504.

The direct hybrid bond structure as shown in FIG. 5 can be implemented between planar surfaces of the first semiconductor chip 104 and the interposer 106 as aforementioned. The direct hybrid bond structure as shown in FIG. 5 can also be implemented between planar surfaces of the first semiconductor chip 104 and the second semiconductor chip 102 as shown in FIG. 4. In some embodiments, the second semiconductor chip 102 is a memory stack, which includes a plurality of memory layers 122 (such as 122A, 122B, 122C, . . . ) stacked on top of one another and then stacked on a logic base layer 124 as shown in FIG. 4. The direct hybrid bond structure as shown in FIG. 5 can also be implemented between planar surfaces of adjacent layers of the memory stack 102. More details will be explained below with respect to FIG. 4.

As shown in FIG. 4, in some embodiments, the first semiconductor chip 104 and the second semiconductor chip 102 are bonded to each other by a direct hybrid bond that is formed between the backside surface 104B of the first semiconductor chip 104 and a bottom surface of the second semiconductor chip 102. In some embodiments, the direct hybrid bond is formed by a plurality of third bonding pad metals (BPMs) 154 embedded into and flush with the backside surface 104B of the first semiconductor chip 104 and a plurality of fourth bonding pad metals 152 embedded into and flush with the bottom surface of the second semiconductor chip 102. In some embodiments, the plurality of third bonding pad metals (BPMs) 154 and the plurality of fourth bonding pad metals 152 are respectively aligned to and in contact with each other, thereby the direct hybrid bond being formed between the backside surface 104B of the first semiconductor chip 104 and a bottom surface of the second semiconductor chip 102. As such, no space or gap exists between the front surface 104F of the first semiconductor chip 104 and the top surface of the interposer 106.

Also as shown in FIG. 4, in some embodiments, the second semiconductor 102 is a memory stack 102 (e.g., a DRAM stack). In some embodiments, the memory stack 102 is a high bandwidth memory stack 102. In some embodiments, the memory stack 102 includes a plurality of memory layers 122 (such as 122A, 122B, 122C, . . . ) stacked on top of one another, and a logic base layer 124 on which the plurality of memory layers 122 are stacked. The logic base layer 124 provides a space for one or more logic circuits that are primarily concerned with performing logical operations on input signals, while the memory stack 102 provides another space for one or more memory circuits that focus on storing and retrieving digital information. In an embodiment, the plurality of fourth bonding pad metals (BPMs) 152 are embedded into and flush with the bottom surface of the logic base layer 124. In some embodiments, a first layer 122A and a second layer 122B of the memory stack 102 positioned adjacent to each other and respectively having a fifth surface and a sixth surface facing each other are bonded by a direct hybrid bond that is formed between the fifth surface of the first layer 122A and the sixth surface of the second layer 122B of the memory stack 102. In some embodiments, the direct hybrid bond is formed by a plurality of bonding pad metals (BPMs) 164 embedded into and flush with a top surface of the first layer 122A and a plurality of bonding pad metals (BPMs) 162 embedded into and flush with a bottom surface of the adjacent second layer 122B. The plurality of bonding pad metals (BPMs) 164 and the plurality of bonding pad metals (BPMs) 162 are respectively aligned to and in contact with each other, thereby the direct hybrid bond is formed between the top surface of the first layer 122A and the bottom surface of the second layer 122B of the memory stack 102. As such, no space or gap exists between the top surface of the first layer 122A and the bottom surface of the adjacent second layer 122B of the memory stack 102.

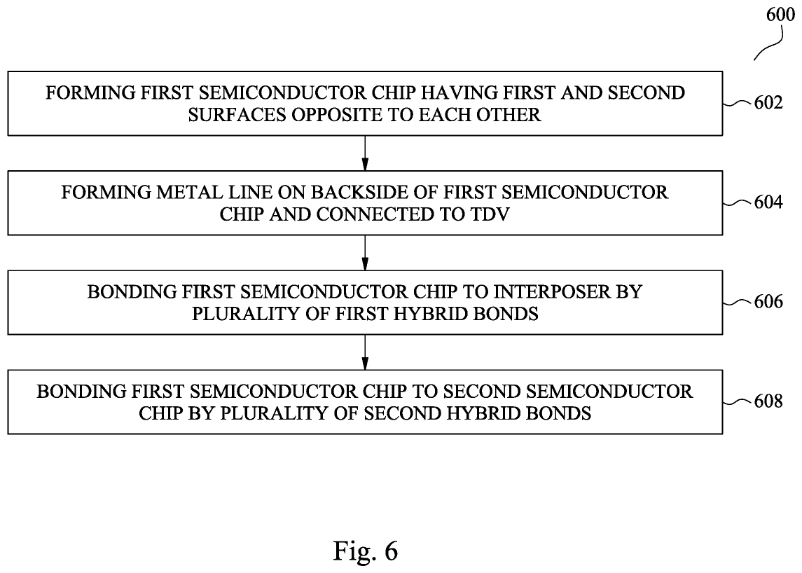

FIG. 6 is an example flowchart of a method 600 for fabricating a semiconductor package 400 in accordance with some embodiments of the present disclosure. It should be noted that the method 600 as shown in FIG. 6 is merely an example, and is not intended to limit the present disclosure. Accordingly, it is understood that the order of operation of the method 600 as shown in FIG. 6 can be changed, for example, additional operations may be provided before, during, and after the method 600 of FIG. 6, and that some other operations may only be described briefly herein.

For example, referring to FIG. 4, the semiconductor package 400 that is fabricated by the method 600 may include at least an interposer 106, a first semiconductor chip 104 disposed over the interposer 106 and having a first surface (e.g., front surface) 104F and a second surface (e.g., back surface) 104B opposite to each other, a second semiconductor chip 102 disposed over the first semiconductor chip 104 and having a top surface and a bottom surface opposite to each other, and a dielectric sidewall 103 disposed along a side of the first semiconductor chip 104 and over the interposer 106. In some embodiments, at least one through dielectric via (TDV) 132 is disposed vertically through the dielectric sidewall 103 and electrically connected to a power distribution network (PDN) (not shown) through the interposer 106. Accordingly, operations of the method 600 will be discussed in conjunction with the components or devices that are discussed with respect to FIG. 4.

Referring to FIGS. 4 and 6, the method 600 starts with operation 602 of forming a first semiconductor chip 104 having a first surface (e.g., front surface) 104F and a second surface (e.g., backside surface) 104B opposite to each other. For example, the first semiconductor chip 104 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the first semiconductor chip 104 may be a SOI substrate. Generally, an SOI substrate includes a layer of a semiconductor material such as epitaxial silicon, germanium, silicon germanium, SOI, SGOI, or combinations thereof.

For example, as shown in FIG. 4, the first semiconductor chip 104 includes a dielectric sidewall 103 along a side thereof and over a top surface of the interposer 106. In some embodiments, one or more through dielectric vias (TDVs) 132 are formed vertically through the dielectric sidewall 103 of the first semiconductor chip 104. In some embodiments, the first semiconductor chip 104 is a GPU chip. Specifically, the TDVs 132 can be formed by semiconductor fabricating processes, such as photolithography, etching, filling of metal, CMP processes, and the like, or a combination thereof.

After that, the first semiconductor chip 104 is flipped, as such the first surface (on the frontside) 104F of the first semiconductor chip 104 faces down and the second surface (on the backside) 104B of the first semiconductor chip 104 faces up. In some embodiments, after flipping the first semiconductor chip 104, one or more through silicon vias (TSVs) 134 passing through a silicon portion 116 of the first semiconductor chip 104 are formed. Specifically, the TSVs 134 can be formed by semiconductor fabricating processes, such as photolithography, etching, filling of metal, CMP processes, and the like, or a combination thereof.

Next, referring to FIGS. 4 and 6, the method 600 proceeds to operation 604 of forming a metal line 136 on a backside 104B of the first semiconductor chip 104. For example, the metal line 136 is connected to the TDVs 132 and the TSVs 134. Specifically, the metal line 136 can be formed by semiconductor fabricating processes, such as photolithography, etching, filling of metal, CMP processes, and the like, or a combination thereof.

Next, referring to FIGS. 4 and 6, the method 600 proceeds to operation 606 of bonding the first semiconductor chip 104 to an interposer 106 that is disposed under the first semiconductor chip 104 by a first direct hybrid bond that is formed between the first surface (e.g., the front surface) 104F of the first semiconductor chip 104 and a top surface of the interposer 106. For example, as shown in FIG. 4, the first direct hybrid bond is formed by a plurality of first bonding pad metals (BPMs) 142 that are embedded into and flush with the first surface 104F of the first semiconductor chip 104 and a plurality of second bonding pad metals (BPMs) 144 that are embedded into and flush with the top surface of the interposer 106.

Next, referring to FIGS. 4 and 6, the method 600 proceeds to operation 608 of bonding the first semiconductor chip 104 to a second semiconductor chip 102 that is disposed over the first semiconductor chip 104 by a second direct hybrid bond that is formed between the second surface (e.g., the back surface) 104B of the first semiconductor chip 104 and a bottom surface of the second semiconductor chip 102. For example, the second direct hybrid bond is formed by a plurality of third bonding pad metals (BPMs) 154 that are embedded into and flush with the second surface (e.g., the back surface) of the first semiconductor chip 104 and a plurality of fourth bonding pad metals (BPMs) 152 that are embedded into and flush with the bottom surface of second semiconductor chip 102.

In some embodiments of the present disclosure, the second semiconductor chip 102 includes a memory stack. In some embodiments, the memory stack 102 includes a high bandwidth memory (HBM) stack. In some embodiments, the HBM stack 102 includes a logic base layer 124, and a plurality of HBM layers 122 (such as 122A, 122B, 122C, . . . ) stacked on top of one another and disposed over the logic base layer 124. In some embodiments, a first layer 122A and a second layer 122B of the HBM stack 102 positioned adjacent to each other and respectively having a third surface and a fourth surface facing each other are bonded by a third direct hybrid bond that is formed between the third surface of the first layer 122A and the fourth surface of the second layer 122B of the HBM stack 102. In some embodiments, the third direct hybrid bond is formed through a plurality of fifth bonding pad metals (BPM) 164 that are embedded into and flush with the third surface of the first layer 122A of the HBM stack 102 and a plurality of sixth bonding pad metals (BPM) 162 that are embedded into and flush with the fourth surface of the second layer 122B of the HBM stack 102.

With these stacking arrangements and bonding structures, such as the TDVs passing through sidewalls of a bottom semiconductor ship and direct hybrid bonding structures between various adjacent surfaces in a 3D semiconductor package, interfacing layers in the 3D semiconductor package are reduced, interface thermal resistances thereof are diminished, and an independent power distribution network is also achieved, thereby advantageously improving the system and power integrations of the 3D semiconductor package.

In one aspect of the present disclosure, a semiconductor package is disclosed. The semiconductor package can include an interposer; a first semiconductor chip disposed over the interposer, and having a first surface and a second surface opposite to each other; a second semiconductor chip disposed over the first semiconductor chip, and having a top surface and a bottom surface opposite to each other; and a dielectric sidewall disposed along a side of the first semiconductor chip and over the interposer. At least one through dielectric via (TDV) is disposed vertically through the dielectric sidewall and electrically connected to a power distribution network (PDN).

In another aspect of the present disclosure, a semiconductor package is disclosed. The semiconductor package can include a first semiconductor chip disposed over an interposer, and having a first surface and a second surface opposite to each other; and at least one dielectric sidewall disposed along a side of the first semiconductor chip and over the interposer. At least one through dielectric via (TDV) is disposed vertically through the dielectric sidewall and electrically connected to a power distribution network (PDN) via the interposer.

In yet another aspect of the present disclosure, a method of fabricating a semiconductor package is disclosed. The method can include forming a first semiconductor chip having a first and a second surfaces opposite to each other, in which the first semiconductor chip includes a dielectric sidewall along a side thereof, at least one through dielectric via (TDV) is formed vertically through the dielectric sidewall, and the first semiconductor chip is flipped; forming a metal line on a backside of the first semiconductor chip and connected to the TDV; bonding the first semiconductor chip to an interposer under the first semiconductor chip by a plurality of first hybrid bonds between the first surface of the first semiconductor chip and a top surface of the interposer; and bonding the first semiconductor chip to a second semiconductor chip over the first semiconductor chip by a plurality of second hybrid bonds between the second surface of the first semiconductor chip and a bottom surface of the second semiconductor chip.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer;
a first semiconductor chip disposed over the interposer, and having a first surface and a second surface opposite to each other;
a second semiconductor chip disposed over the first semiconductor chip, and having a top surface and a bottom surface opposite to each other; and
a dielectric sidewall disposed along a side of the first semiconductor chip and over the interposer, wherein at least one first via structure is disposed vertically through the dielectric sidewall and electrically connected to a power distribution network (PDN).

2. The semiconductor package of claim 1, wherein the first semiconductor chip and the interposer are bonded to each other by a plurality of first hybrid bonds between the first surface of the first semiconductor chip and a top surface of the interposer.

3. The semiconductor package of claim 2, wherein the plurality of first hybrid bonds are formed by a plurality of first bonding pad metals (BPMs) embedded into and flush with the first surface of the first semiconductor chip and a plurality of second bonding pad metals embedded into and flush with the top surface of the interposer.

4. The semiconductor package of claim 1, wherein the first semiconductor chip and the second semiconductor chip are bonded to each other by a plurality of second hybrid bonds between the second surface of the first semiconductor chip and the bottom surface of the second semiconductor chip.

5. The semiconductor package of claim 4, wherein the plurality of second hybrid bonds are formed by a plurality of third bonding pad metals embedded into and flush with the second surface of the first semiconductor chip and a plurality of fourth bonding pad metals embedded into and flush with the bottom surface of the second semiconductor chip.

6. The semiconductor package of claim 1, wherein the second semiconductor chip is a high bandwidth memory (HBM) stack that comprises:
a logic base layer; and
a plurality of HBM layers on the logic base layer, and stacked on top of one another.

7. The semiconductor package of claim 6, wherein a first layer and a second layer of the HBM stack respectively having a third surface and a fourth surface facing each other are bonded by a plurality of third hybrid bonds between the third surface of the first layer and the fourth surface of the second layer of the HBM stack.

8. The semiconductor package of claim 7, wherein the plurality of third hybrid bonds are formed through a plurality of fifth bonding pad metals embedded into and flush with the third surface of the first layer of the HBM stack and a plurality of sixth bonding pad metals embedded into and flush with the fourth surface of the second layer of the HBM stack.

9. The semiconductor package of claim 1, wherein the first semiconductor chip comprises a graphics processing unit (GPU) chip.

10. The semiconductor package of claim 1, wherein a backside of the first semiconductor chip faces the bottom surface of the second semiconductor chip, and wherein the first semiconductor chip comprises a metal line on the backside thereof and electrically connected to the first via structure.

11. The semiconductor package of claim 10, wherein the first semiconductor chip comprises at least one a second via structure passing through a silicon portion thereof and electrically connected to the metal line.

12. A semiconductor package, comprising:
a first semiconductor chip disposed over an interposer, and having a first surface and a second surface opposite to each other; and
at least one dielectric sidewall disposed along a side of the first semiconductor chip and over the interposer, wherein at least one a first via structure is disposed vertically through the dielectric sidewall and electrically connected to a power distribution network (PDN) via the interposer.

13. The semiconductor package of claim 12, wherein the first semiconductor chip comprises a metal line on a backside thereof and electrically connected to the first via structure.

14. The semiconductor package of claim 13, wherein the first semiconductor chip comprises at least one second via structure through a silicon portion thereof, and wherein the second via structure is electrically connected to the metal line.

15. The semiconductor package of claim 12, wherein the first semiconductor chip and the interposer are bonded to each other by a plurality of first hybrid bonds between the first surface of the first semiconductor chip and a top surface of the interposer.

16. The semiconductor package of claim 12, further comprising:
a second semiconductor chip disposed over the first semiconductor chip and having a top surface and a bottom surface opposite to each other,
wherein the second semiconductor chip is a high bandwidth memory (HBM) stack that comprises a logic base layer, and plurality of HBM layers on the logic base layer and stacked on top of one another.

17. The semiconductor package of claim 16, wherein the first semiconductor chip and the second semiconductor chip are bonded to each other by a plurality of second hybrid bonds between the second surface of the first semiconductor chip and the bottom surface of the second semiconductor chip.

18. A method of fabricating a semiconductor package, comprising:
forming a first semiconductor chip having a first and a second surfaces opposite to each other, wherein the first semiconductor chip comprises a dielectric sidewall along a side thereof, wherein at least one first via structure is formed vertically through the dielectric sidewall, and wherein the first semiconductor chip is flipped;
forming a metal line on a backside of the first semiconductor chip and connected to the first via structure;
bonding the first semiconductor chip to an interposer under the first semiconductor chip by a plurality of first hybrid bonds between the first surface of the first semiconductor chip and a top surface of the interposer; and
bonding the first semiconductor chip to a second semiconductor chip over the first semiconductor chip by a plurality of second hybrid bonds between the second surface of the first semiconductor chip and a bottom surface of the second semiconductor chip.

19. The method of claim 18, wherein the plurality of first hybrid bonds are formed by a plurality of first bonding pad metals (BPMs) embedded into and flush with the first surface of the first semiconductor chip and a plurality of second bonding pad metals embedded into and flush with the top surface of the interposer.

20. The method of claim 18, wherein the plurality of second hybrid bonds are formed by a plurality of third bonding pad metals embedded into and flush with the second surface of the first semiconductor chip and a plurality of fourth bonding pad metals embedded into and flush with the bottom surface of the second semiconductor chip.
